(19) United States
(12) Patent Application Publication
(10) Pub. No.: US 2008/0160742 A1
(43) Pub. Date: Jul. 3, 2008

(54) METHOD FOR FABRICATING SEMICONDUCTOR DEVICE WITH RECESS GATE

(75) Inventors: Yong-Tae CHO, Ichon-shi (KR); Hae-Jung LEE, Ichon-shi (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Ichon-shi (KR)

(21) Appl. No.: 11/963,989

(22) Filed: Dec. 24, 2007

(30) Foreign Application Priority Data
Dec. 27, 2006 (KR) 10-2007-0134299

(51) Int. Cl. H01L 21/3205

(52) U.S. Cl. 438/589; 257/E21.294

(57) ABSTRACT

A method for fabricating a semiconductor device having a recess gate includes forming a first recess pattern by etching the substrate and a sidewall protection layer on sidewalls of the first recess pattern, forming a second recess pattern having a greater width than the first recess pattern by etching a certain portion of the substrate below a bottom portion of the first recess pattern, and forming a gate electrode filling the first and the second recess patterns.

### CROSS-REFERENCE TO RELATED APPLICATIONS

The present invention claims priority to Korean patent application number 2006-0134299, filed on Dec. 27, 2006, which is incorporated by reference in its entirety.

### BACKGROUND OF THE INVENTION

The present invention generally relates to a method for fabricating a semiconductor device, and more particularly, to a method for fabricating a recess pattern in a semiconductor device.

As the scale of integration of a semiconductor device increases, a gate channel length decreases and an ion implantation density increases when employing a conventional method of forming a gate over a planar active region. As a result, an electronic field increases and thus a junction leakage occurs. Therefore, it is difficult to secure a refresh characteristic of the semiconductor device.

To secure the refresh characteristic of the semiconductor device, a technology for forming a recess gate structure, i.e., a 3D gate structure, is introduced. In the 3D gate structure, a region under a gate pattern is recessed to increase a channel length.

FIG. 1 illustrates a cross-sectional view of a typical recess pattern in a semiconductor device.

Referring to FIG. 1, an isolation layer 102 is formed over a substrate 101, and an oxide layer 103 and an amorphous carbon layer 104 are formed over the substrate 101. Then, a region for forming a recess is defined by removing some portions of the amorphous carbon layer 104 and the oxide layer 103 and some portions of the substrate 101 are etched using the amorphous carbon layer 104 and the oxide layer 103 as a mask to form a recess pattern 105. Thus, a channel length increases and the ion implantation density decreases, so that the refresh characteristic of the semiconductor device is improved.

However, as the semiconductor device is fabricated with micronized patterns, a size of the recess pattern 105 decreases and assumes a “V”-type profile. Thus, a horn 100 (as shown in FIG. 2) is generated between the recess pattern 105 and the adjacent isolation layer 102.

The horn becomes more serious when forming the isolation layer 102 to have a slope profile for a gap-fill characteristic of an insulation layer in addition to the recess pattern 105 having the “V” profile.

Characteristics of a subsequent gate oxide layer are deteriorated by the horn. That is, a stress is concentrated on the horn and, thus, the horn functions as a leakage source, so that there occurs a yield drop of the semiconductor devices.

### SUMMARY OF THE INVENTION

Embodiments of the present invention are directed to provide a method for fabricating a semiconductor device having a recess gate, which method can prevent a leakage and a yield drop caused by a horn while forming a recess pattern.

In accordance with an aspect of the present invention, there is provided a method for fabricating a semiconductor device having a recess gate. The method includes forming a first recess pattern by etching the substrate and a sidewall protection layer on sidewalls of the first recess pattern, forming a second recess pattern having a greater width than the first recess pattern by etching a certain portion of the substrate below a bottom portion of the first recess pattern, and forming a gate electrode filling the first and the second recess patterns.

### BRIEF DESCRIPTION OF THE DRAWINGS

FIG. 1 illustrates a cross-sectional view of a typical recess pattern in a semiconductor device.

FIG. 2 illustrates a micrographic view of a typical recess pattern in a semiconductor device.

FIGS. 3A to 3F illustrate cross-sectional views of a method for fabricating a recess pattern in a semiconductor device in accordance with the present invention.

FIGS. 4A to 4B are micrographic views of an oxide layer in accordance with embodiments of the present invention.

FIGS. 5A to 5B are micrographic views for comparing the present invention to a prior art.

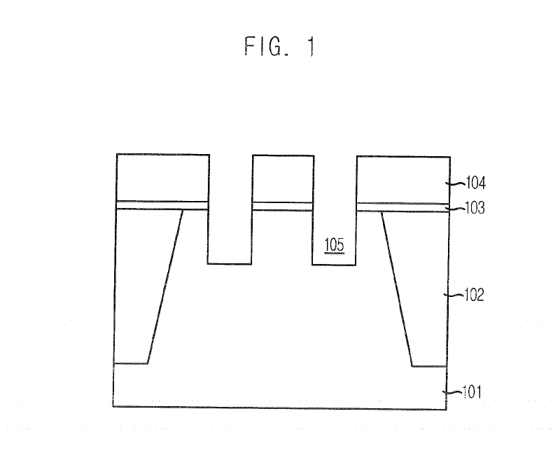

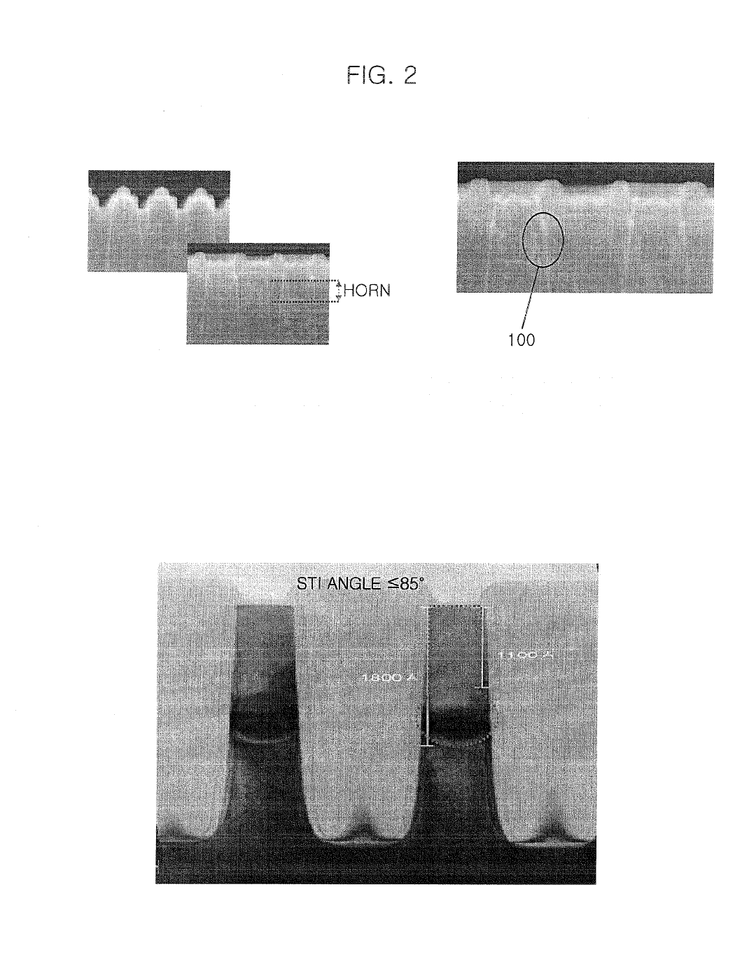

### DESCRIPTION OF SPECIFIC EMBODIMENTS

Embodiments of the present invention relate to a method for fabricating a semiconductor device with a recess gate.

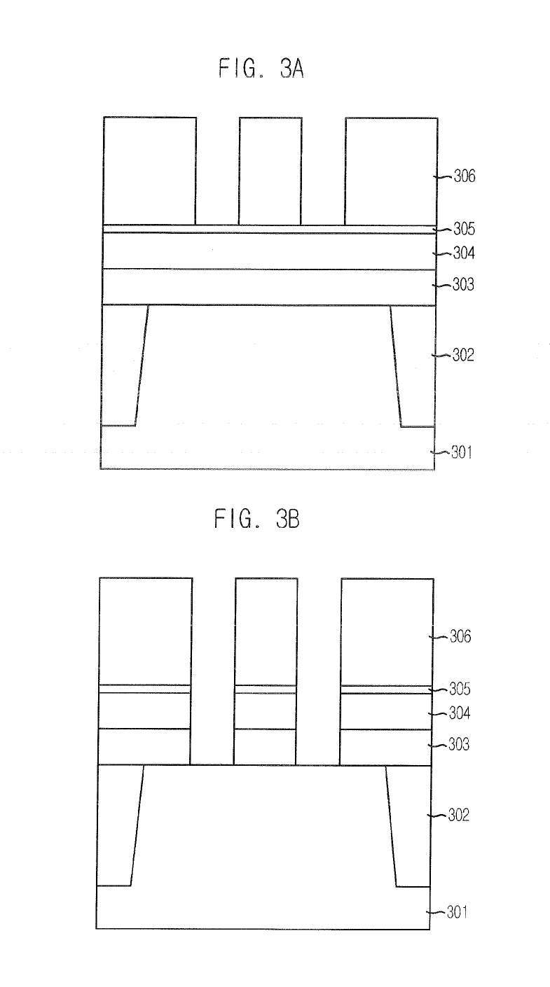

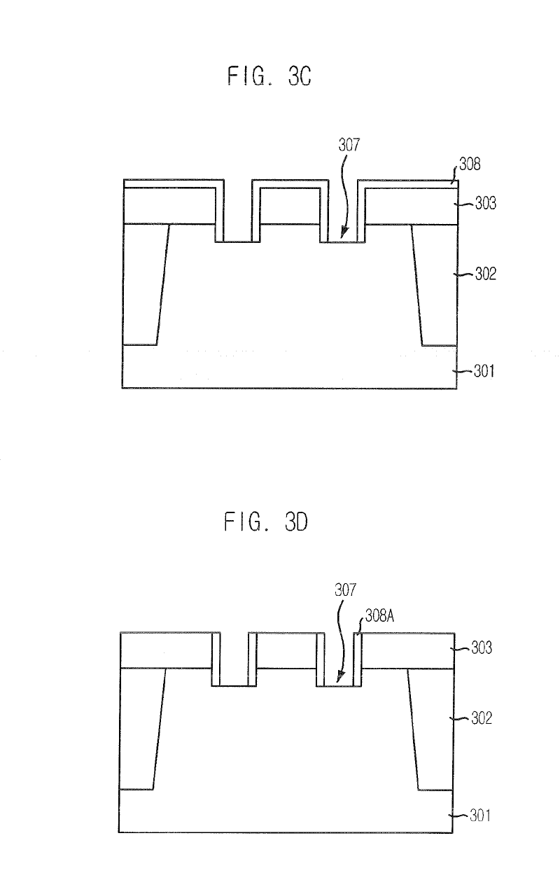

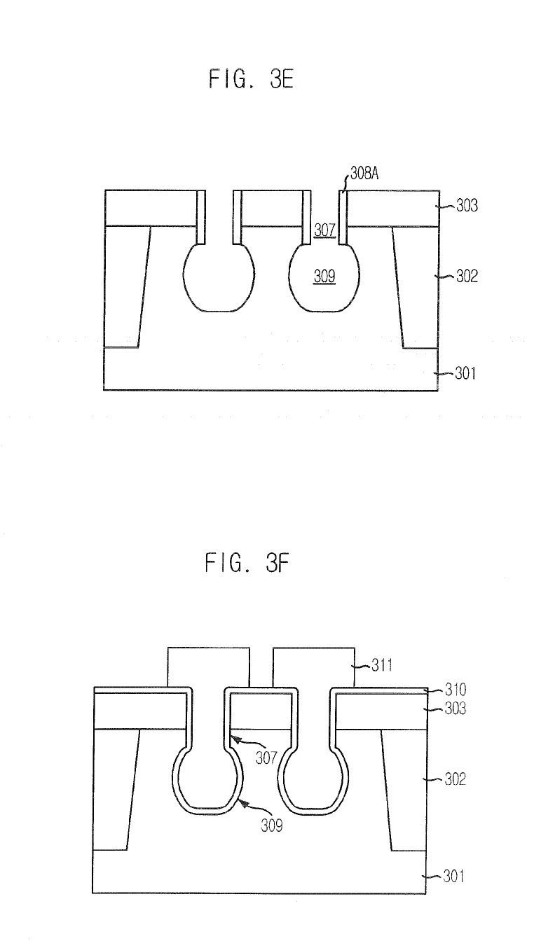

FIGS. 3A to 3F illustrate cross-sectional views of a method for fabricating a recess pattern in a semiconductor device in accordance with the present invention.

Referring to FIG. 3A, an isolation layer 302 is formed over a substrate 301. The substrate 301 may be a semiconductor substrate for performing a dynamic random access memory (DRAM) fabrication process. The isolation layer 302 is formed using a shallow trench isolation (STI) method. In a process of forming a trench in the substrate 301 and filling the trench with an insulation layer, the trench may be formed to have a slope profile to secure a gap-fill characteristic of the insulation layer.

Then, a sacrificial oxide layer 303 and an amorphous carbon layer 304 are formed over the substrate 301 including the isolation layer 302. The sacrificial oxide layer 303 is used as a hard mask to form a subsequent recess pattern and the amorphous carbon layer 304 is used as a hard mask to etch the sacrificial oxide layer 303.

An anti-reflection coating (ARC) layer 305 is formed over the amorphous carbon layer 304. The ARC layer 305 is used to prevent a reflection from occurring when forming a subsequent photoresist pattern.

A photoresist pattern 306 is formed over the ARC layer 305. The photoresist pattern 306 is formed by coating a photoresist layer over the ARC layer 305 and patterning the photoresist layer through an photo-exposure and a development process, opening a region where a recess will be formed.

Referring to FIG. 3B, the ARC layer 305, the amorphous carbon layer 304, and the sacrificial oxide layer 303 are etched by using the photoresist pattern 306 as a mask.

The amorphous carbon layer 304 is etched until the sacrificial layer 303 is opened using plasma with a gas mixture of N₂ and O₂ in a magnetically enhanced reactive ion beam etching (MERIE) type plasma system.

The sacrificial oxide layer 303 is etched using plasma generated by adding an oxygen (O₂) gas to a gas mixture of a CF-based gas and a CHF-based gas.

Referring to FIG. 3C, the photoresist pattern 306, the ARC layer 305, and the amorphous carbon layer 304 are removed. The photoresist pattern 306 and the ARC layer 305 may be removed when etching the amorphous carbon layer 304 and the sacrificial oxide layer 303 in FIG. 3B or may be removed when removing the amorphous carbon layer 304.

The amorphous carbon layer 304 is removed using plasma generated from an O₂ gas of approximately 200 sccm to approximately 1,000 sccm.

Subsequently, the substrate 301 is partially etched using the sacrificial layer 303 as an etch barrier to form a first recess pattern 307 therein. At the same time, a plasma oxide layer 308 is formed over the substrate 301 including the first recess pattern 307. That is, the etch process is performed by providing a gas mixture of an etch gas for forming the first recess pattern 307 and an oxide gas for forming the plasma oxide layer 308, so that the first recess pattern 307 and the plasma oxide layer 308 are simultaneously formed.

HBr may be used as an etch gas for forming the first recess pattern 307. A gas mixture of O₂ and N₂ or a gas mixture of O₂ and CHₓF_{y} may be used as an oxide gas for forming the plasma oxide layer 308. The CHₓF_{y} may be CHF₃ or CH₂F₂. A gas mixture of O₂ and N₂ can form the plasma oxide layer 308 to have a greater thickness.

To simultaneously form the first recess pattern 307 and the plasma oxide layer 308, the etch process thereafter is performed in a high density plasma system, e.g., a transformer coupled plasma (TCP) system or an inductively coupled plasma (ICP) system in condition of a pressure ranging from approximately 5 mT to approximately 20 mT, a source power ranging from approximately 700 W to approximately 1,500 W, and a bottom power ranging from approximately 200 Å to approximately 500 Å, wherein the first recess pattern 307 has a depth ranging from approximately 200 Å to approximately 500 Å. Also, the etch process may be performed in one selected from a group consisting of a microwave down stream (MDS) system, an electron cyclotron resonance (ECR) system, and a helical system.

When forming the first recess pattern 307, the etch process is performed by adding the gas mixture of O₂ and N₂ or the gas mixture of O₂ and CHₓF_{y} to form the plasma oxide layer 308. As a result, a surface of the substrate 301 exposed by the etch process is plasma oxidized, and, thus, the plasma oxide layer 308 is formed without performing a separate oxidation process

Referring to FIG. 3D, the plasma oxide layer 308 in a bottom portion of the first recess pattern 307 is etched. The plasma oxide layer 308 remains on sidewalls of the first recess pattern 307 to form a sidewall protection layer 308A. A slimming process can be performed to etch the plasma oxide layer 308.

Referring to FIG. 3E, a portion of the substrate 301 below the bottom portion of the first recess pattern 307 is etched to form a second recess pattern 309 having a width greater than that of the first recess pattern 307.

The second recess pattern 309 is formed by etching the portion of the substrate 301 below the bottom portion of the first recess pattern 308 and widening the etched portion of the substrate 301. The second recess pattern 309 may be formed in the same chamber used when forming the first recess pattern 307 by in-situ process.

First, the etch process is performed using a gas mixture of HBr and Cl₂, which are mixed in a flow ratio of approximately 0.5 to 2:1 to form the second recess pattern 309. To form the second recess pattern 309, the substrate 301 is further etched to a depth ranging from approximately 700 521 to approximately 1,000 Å from the bottom of the first recess pattern 307 in conditions of a pressure ranging from approximately 10 mT to approximately 30 mT, a top power ranging from approximately 500 W to approximately 1,000 W, and a bottom power ranging from approximately 200 W to approximately 500 W. A first isotropic etch is performed for a middle portion of the second recess pattern 309 to have a bowing profile. Thus, the generation of a horn is minimized, the horn being formed between the first and second recess patterns 307 and 309 and their adjacent isolation layer 302.

The isotropic etch is performed to expand the width of the second recess pattern 309. The isotropic etch is performed by adding an O₂ gas and a fluorine-based gas to a gas mixture of HBr and Cl₂. The fluorine-based gas is one selected from a group consisting of SF₆, CF-based gas and NF-based gas. The etch process is performed by applying a pressure ranging from approximately 20 mT to approximately 100 mT, a source power ranging from approximately 500 W to approximately 1,500 W, and a bottom power ranging from approximately 1 W to approximately 50 W or no bottom power, so that the width of the second recess pattern 309 is extended as much as approximately 10 nm to approximately 15 nm.

As described above the second recess pattern 309 is formed, to have a greater width than the first recess pattern 307 and the bowing profile. By extending the width, the horn generated between the first and the second recess patterns 307 and 309 and their adjacent isolation 302 can be minimized. Since the point where the horn is generated is located in the depth of forming the second recess pattern 309. It is possible to extend the width of the second recess pattern 309 while protecting only the sidewalls of the first recess pattern 307 by forming the sidewall protection layer 308A on the sidewalls of the first recess pattern 307. As a result, a fine pattern can be formed.

Referring to FIG. 3F, the sidewall protection layer 308A and the sacrificial oxide layer 303 are removed.

A gate insulation layer 310 is formed over the substrate 301 including the first and the second recess patterns 307 and 309. The gate insulation layer 310 may include an oxide layer. As shown in FIG. 3E, the second recess pattern 309 having the bowing profile and the greater width than the first recess pattern 307 is formed to minimize the horn adjacent to the isolation layer 302. Thus, the thermal aging of the gate insulation layer 310 can be prevented.

Then a gate electrode 311 is formed over the gate insulation layer 310 to fill the first and the second recess patterns 307 and 309 and to be projected onto a top surface of the gate insulation layer 310.

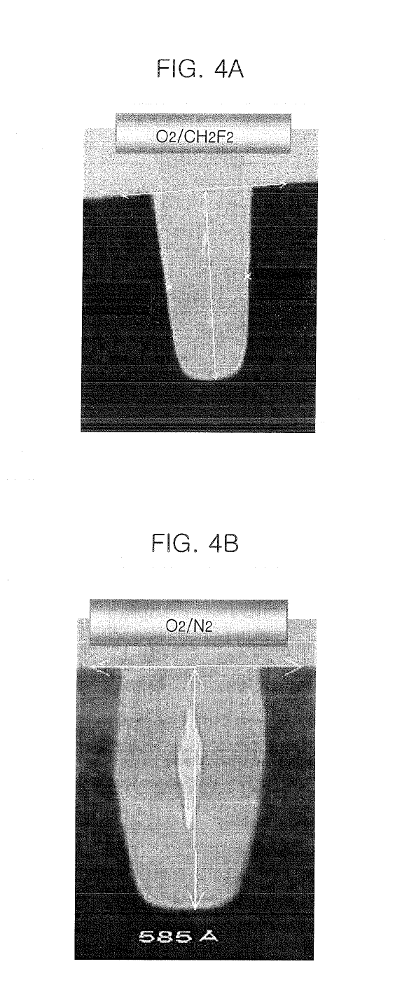

FIGS. 4A and 4B are micrographic views of an oxide layer in accordance with the embodiments of the present invention.

Referring to FIGS. 4A and 4B, the oxide layer is formed by adding a gas mixture of O₂ and N₂ or a gas mixture of O₂ and CH₂F₂ to form the recess pattern.

Both of the gas mixture of O₂ and N₂ and the gas mixture of O₂ and CH₂F₂ used in this invention can form the plasma oxide layer. Specially, the gas mixture of O₂ and N₂ can form a thicker oxide layer.

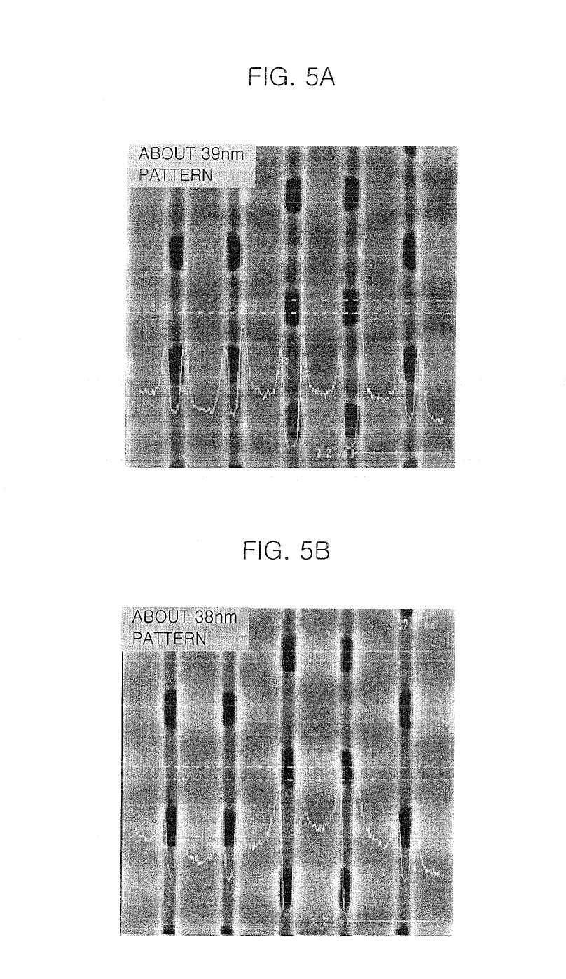

FIGS. 5A and 5B are micrographic views for comparing this invention to a prior art.

Referring to FIGS. 5A and 5B, a typical horn in FIG. 5A is clearly shown while there scarcely exists a horn in FIG. 5B illustrating the present invention.

As describe above, in accordance with the present invention, when the first recess pattern 307 is formed, the sidewall protection layer 308A is also formed on the sidewalls of the first recess pattern 307. Therefore, by etching the bottom portion of the first recess pattern 307 in order to remove the horn, the second recess pattern 309 having the greater width than the first recess pattern 307 is formed while protecting the sidewalls of the first recess pattern 307, so that the fine pattern can be formed.

Also, by extending the width of the second recess pattern 309 through the isotropic etching, the horn generated in an area between the first and the second recess patterns 307 and 309 and the isolation layer 302 can be removed. As a result, the thermal aging of the gate insulation layer 310 can be prevented, and it is possible to avoid a leakage accruing at the horn.

By performing the isotropic etching on the second recess pattern 309, the generation of a “V”-type profile can be suppressed. Thus, the horn is removed, a sufficient channel length is secured, and the ion implantation density decreases.

In accordance with the present invention, although the isolation layer is formed to have a slope profile for a gap-fill and a size reduction so that a recess pattern is stably formed in the process for patterning a semiconductor device into a micronized pattern and the horn between the recess pattern and the adjacent isolation layer becomes bigger, it is possible to minimize the generation of the horn by forming the sidewall protection layer an the sidewalls of the proper portion of the recess pattern and providing the recess pattern having a dual profile recess whose lower portion is wider than the upper portion.

Thus, a weakpoint, i.e., a stress concentration point, is removed, which causes the leakage. Furthermore, the channel length is secured and the ion implantation density decreases, thereby substantially improving a refresh performance of the semiconductor device.

As a result, it is possible to provide a secured deign rule and a maximized process margin, which incur large-scale integration, an increased yield, and a reduced unit production cost of the semiconductor device.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device having a recess gate, the method comprising:
forming a first recess pattern by etching a substrate and a sidewall protection layer on sidewalls of the first recess pattern;
forming a second recess pattern having a greater width than the first recess pattern by etching a certain portion of the substrate below a bottom portion of the first recess pattern; and
forming a gate electrode filling the first and the second recess patterns.

2. The method of claim 1, wherein forming the first recess pattern and the sidewall protection layer comprises etching the substrate together with oxidizing the substrate.

3. The method of the claim 2, wherein etching the substrate uses hydrogen bromide (HBr).

4. The method of claim 2, wherein oxidizing the substrate is performed by plasma oxidation.

5. The method of claim 4, wherein the plasma oxidation is performed using a gas mixture of oxygen (O₂) and nitrogen (N₂) or a gas mixture of O₂ and CHₓF_{y}.

6. The method of claim 5, wherein the CHₓF_{y} is fluoroform (CHF₃) or difluoromethane (CH₂F₂).

7. The method of claim 1, wherein forming the first recess pattern and the sidewall protection layer is performed using a transformer coupled plasma (TCP) system or a inductively coupled plasma (ICP) system.

8. The method of claim 1, wherein forming the first recess pattern and the sidewall protection layer is performed to form the first recess pattern having a depth ranging from approximately 200 Å to approximately 500 Å by applying a pressure ranging from approximately 5 mT to approximately 20 mT, a source power ranging from approximately 700 W to approximately 1,500 W, and a bottom power ranging from approximately from 200 Å to approximately 500 Å.

9. The method of claim 1, wherein forming the first recess pattern and the sidewall protection layer is performed in one selected from a group consisting of a microwave down stream (MDS) system, an electron cyclotron resonance (ECR) system, and a helical system.

10. The method of claim 1, wherein forming the second recess pattern is performed in the same chamber used when forming the first recess pattern by in-situ process.

11. The method of claim 1, wherein forming the second recess pattern is performed using a gas mixture of HBr and chlorine (Cl₂).

12. The method of claim 11, wherein a flow ratio of HBr to Cl₂ in the gas mixture is approximately 0.5 to 2:1.

13. The method of claim 1, wherein forming the second recess pattern is performed by applying a pressure ranging from approximately 10 mT to approximately 30 mT, a top power ranging from approximately 500 W to approximately 1,000 W, and a bottom power ranging from approximately 200 W to approximately 500 W.

14. The method of claim 1, wherein forming the second recess pattern is performed by etching the substrate to a depth ranging from approximately 700 Å to approximately 1,000 Å from the bottom portion of the first recess pattern extending a middle portion of the second recess pattern having a bowing profile.

15. The method of claim 1, further comprising, widening the width of the second recess pattern after forming the second recess pattern.

16. The method of claim 15, wherein extending the width of the second recess pattern is performed by isotropic etching.

17. The method of claim 16, wherein the isotropic etching is performed by adding a fluorine-based gas to a gas mixture of HBr and Cl₂.

18. The method of claim 17, wherein the fluorine-based gas is one selected from a group consisting of sulfur hexafluoride (SF₆), CF-based and NF-based gas.

19. The method of claim 18, wherein extending the width of the second recess pattern is performed by applying a pressure ranging from approximately 20 mT to approximately 100 mT, a source power ranging from approximately 500 W to approximately 1,500 W, and a bottom power ranging from approximately 1 W to approximately 50 W.

20. The method of claim 16, wherein extending the width of the second recess pattern is extended as much as approximately 10 nm to approximately 15 nm.
